(19) United States
(12) Patent Application Publication
(10) Pub. No.: US 2025/0189923 A1
(43) Pub. Date: Jun. 12, 2025

(54) CIRCUIT BOARD AND IMAGE FORMING APPARATUS

(71) Applicant: CANON KABUSHIKI KAISHA, Tokyo (JP)

(72) Inventor: YOSHIFUMI TAKAO, Chiba (JP)

(21) Appl. No.: 18/973,869

(22) Filed: Dec. 9, 2024

(30) Foreign Application Priority Data
Dec. 11, 2023 (JP) 2023-208451

(51) Int. Cl. G03G 15/00; H05K 1/11

(52) U.S. Cl. CPC G03G 15/80; G03G 15/50; H05K 1/115; H05K 2201/10545

(57) ABSTRACT

Disclosed is a circuit board comprising a first surface configured so that a first electronic part is mountable, a second surface different from the first surface, the second surface being configured so that a second electronic part is mountable, and a controller configured to generate a first control signal input to the first electronic part to control a logical value of an output signal output by the first electronic part; and a second control signal input to the second electronic part to control a logical value of the output signal output by the second electronic part; and a first via configured to connect a wiring to which the output signal from the first electronic part is output and a wiring to which the output signal from the second electronic part is output.

### BACKGROUND OF THE INVENTION

### Field of the Invention

The present disclosure relates to circuit boards on which electronic parts are mounted, and image forming apparatus such as printers, copying machines, or multifunction machines, including such a circuit board.

### Description of the Related Art

An image forming apparatus includes a plurality of circuit boards for control of a plurality of actuators for forming an image. The circuit boards for control include a circuit board having a function of performing image forming control, and a circuit board having a function of sheet conveyance control. On each circuit board for control, a plurality of electronic parts is mounted in accordance with the function to be implemented. The plurality of electronic parts includes an electronic part for performing a logic operation, an electronic part for performing drive control, and an electronic part for generating a power supply voltage. The electronic parts on the circuit board are connected by a conductor wire such as a printed wiring line. Each electronic part forms, together with its surrounding electronic part, an electronic part component for implementing a predetermined function. For example, the electronic part component is composed of a semiconductor device such as an integrated circuit (IC) and surrounding parts connected to an input/output terminal of the semiconductor device such as a resistor, a capacitor, an inductor, and the like.

The image forming apparatus prints an image on a sheet through a plurality of steps such as sheet conveyance, image formation, image transfer onto a sheet, and fixing of an image to the sheet. Accordingly, the image forming apparatus is required to control a wide variety of actuators, such as an optical sensor, a temperature sensor, a motor, and a solenoid. On the circuit board for control to be installed on the image forming apparatus, a plurality of electronic parts for controlling the actuators are mounted. For example, a driver board for driving a motor includes, in order to control the motor appropriately, a semiconductor device (motor driver IC) for generating a motor drive signal based on a control signal input from a controller (Japanese Patent Application Laid-open No. 2022-6639).

### SUMMARY OF THE INVENTION

A circuit board according to one embodiment of the present disclosure includes a first surface configured so that a first electronic part is mountable, a second surface different from the first surface, the second surface being configured so that a second electronic part is mountable, and a controller configured to generate a first control signal to be input to the first electronic part to control a logical value of an output signal output by the first electronic part, and a second control signal to be input to the second electronic part to control a logical value of an output signal output by the second electronic part, and a first via configured to connect a wiring to which the output signal from the first electronic part is output and a wiring to which the output signal from the second electronic part is output, wherein a logical value of the first control signal and a logical value of the second control signal have an inverse relationship with each other.

An image forming apparatus according to another embodiment of the present disclosure includes a load configured to perform at least part of image forming, and a circuit board, wherein the circuit board includes a first surface configured so that a first electronic part is mountable, a second surface different from the first surface, the second surface being configured so that a second electronic part is mountable, a controller configured to generate a first control signal to be input to the first electronic part to control a logical value of an output signal output by the first electronic part and a second control signal to be input to the second electronic part to control a logical value of an output signal output by the second electronic part, and a first via configured to connect a wiring to which the output signal from the first electronic part is output and a wiring to which the output signal from the second electronic part is output, wherein the logical value of the first control signal and the logical value of the second control signal have inverse relationship with each other, and wherein the first electronic part is mounted on the circuit and the second electronic part is not mounted on the circuit.

Further features of the present invention will become apparent from the following description of exemplary embodiments (with reference to the attached drawings).

### BRIEF DESCRIPTION OF THE DRAWINGS

FIG. 1 is a system configuration diagram of an image forming apparatus.

FIG. 2 is a configuration view of the image forming apparatus.

FIG. 3 is a configuration diagram of a circuit board.

FIG. 4 is an explanatory diagram of electronic part components.

FIGS. 5A and 5B are explanatory views of a mounting surface of the circuit board.

FIG. 6 is a configuration diagram of a modified example of a circuit board.

FIG. 7 is an explanatory diagram of a modified example of electronic part components.

FIG. 8 is a flowchart illustrating a process for determining a DIR signal logic.

### DESCRIPTION OF THE EMBODIMENTS

Now, description is given of at least one exemplary embodiment of the present disclosure with reference to the accompanying drawings. Note that a configuration of an apparatus or a circuit described in this embodiment is simply an example. Therefore, not limited to this, other configuration or determination procedure may be adopted.

In the embodiments, in order to arrange more electronic part components, electronic parts are arranged on both surfaces of a circuit board. However, in the prior art, logical values of control signals supplied to these electronic parts has not been sufficiently considered. Therefore, it was difficult to obtain appropriate signal outputs depending on arrangements of the electronic parts. In some implementations, appropriate signal outputs can be obtained.

### Configuration of Image Forming Apparatus

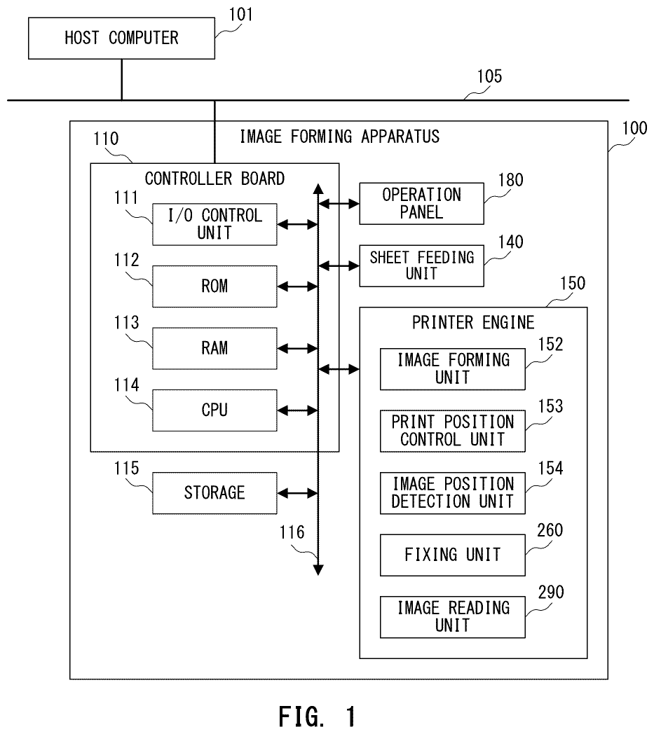

FIG. 1 is a system configuration diagram of an image forming apparatus including a circuit board according to at least one embodiment of the present disclosure. It should be understood that, unless otherwise described, an image forming apparatus 100 may be a system including a plurality of apparatus connected to each other via a network, as long as functions of the image forming apparatus 100 can be implemented.

The image forming apparatus 100 according to the at least one embodiment is connected to a host computer 101 via a network 105 so that communication is allowed therebetween. The network 105 includes a communication line such as a local area network (LAN), a wide area network (WAN), and a public communication line. A plurality of image forming apparatus 100 and a plurality of host computers 101 may be connected to the network 105. The host computer 101 generates a print job based on input information from a user acquired from an input device (not shown), and transmits the generated print job to the image forming apparatus 100 via the network 105.

The image forming apparatus 100 includes a controller board 110, a storage 115, a sheet feeding unit 140, a printer engine 150, and an operation panel 180. The controller board 110, the storage 115, the sheet feeding unit 140, the printer engine 150, and the operation panel 180 are connected to each other via a system bus 116 so that mutual communication is allowed therebetween.

The controller board 110 includes an I/O control unit 111, a read only memory (ROM) 112, a random access memory (RAM) 113, and a central processing unit (CPU) 114. The I/O control unit 111, the ROM 112, the RAM 113, and the CPU 114 are electronic parts mounted on a circuit board. The controller board 110 functions as a main control unit of the image forming apparatus 100, performs various data processing, and controls the entire operation of image forming apparatus 100. The circuit board is, for example, a printed wiring board having printed wiring formed thereon.

The I/O control unit 111 controls communication to/from an external apparatus such as the host computer 101 via the network 105. The CPU 114 executes a computer program stored in the ROM 112 and the storage 115 to control an operation such as image forming processing to be performed by the image forming apparatus 100. The RAM 113 provides a work area used in a case where the CPU 114 executes processing, and performs storage of temporal data or the like.

The storage 115 stores large-capacity data, such as image data or print data, on a temporary or long-term basis. For example, the storage 115 stores image data for generating an image for adjustment for use in adjusting an image forming condition. The storage 115 is a large-capacity storage device, such as a hard disk drive (HDD) or a solid state drive (SSD). Computer programs, such as a startup program, a control program, and an operation system, to be executed by the CPU 114 are stored in the ROM 112 and the storage 115.

The operation panel 180 is a user interface including an input interface and an output interface. The input interface is, for example, key buttons and a touch panel. The output interface is a display, a speaker, and the like. The operation panel 180 receives an instruction or the like through the operation of the user and inputs the received instruction or the like to the CPU 114. The CPU 114 controls the operation of the image forming apparatus 100 in accordance with the instruction acquired from the operation panel 180. Further, the operation panel 180 displays a state of the image forming apparatus 100 and various setting screens in accordance with the instruction from the CPU 114.

The sheet feeding unit 140 includes a sheet feeding device including one or more sheet feeding stages, and an entire conveying unit for conveying a sheet from one of the sheet feeding stages to a sheet discharging unit. The sheet feeding unit 140 feeds sheets one by one from the sheet feeding stage in accordance with the instruction from the CPU 114.

The printer engine 150 includes an image forming unit 152, a print position control unit 153, an image position detection unit 154, a fixing unit 260, and an image reading unit 290. The image forming unit 152 forms an image (toner image) on the sheet fed by the sheet feeding unit 140. The fixing unit 260 fixes the image (toner image) to the sheet. The image reading unit 290 reads the image for adjustment printed on the sheet. The image position detection unit 154 detects an image position printed on the sheet based on results of reading the image for adjustment by the image reading unit 290. The print position control unit 153 controls the position of the image to be printed on the sheet based on the image position detected by the image position detection unit 154.

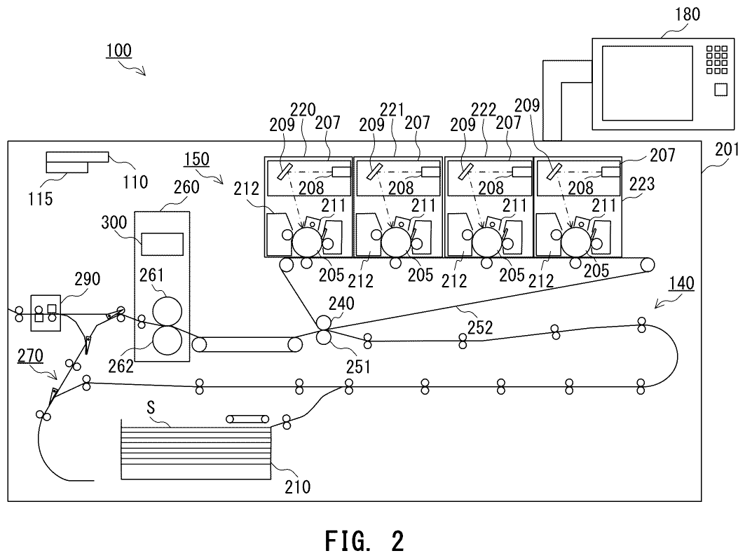

FIG. 2 is a configuration view of the image forming apparatus 100. The image forming apparatus 100 includes the operation panel 180 at the upper portion of a casing 201. Inside of the casing 201, the controller board 110, the storage 115, the sheet feeding unit 140, and the printer engine 150 illustrated in FIG. 1 are provided. The printer engine 150 includes mechanisms forming an engine unit, and an engine control unit for performing control of processing to be performed by each mechanism. The mechanisms forming the engine unit include an optical processing mechanism and a fixing processing mechanism. The optical processing mechanism is used for forming an electrostatic latent image, visualizing the electrostatic latent image, and transferring the visualized image onto a sheet S. The fixing processing mechanism fixes the toner image transferred onto the sheet S.

The image forming unit 152 (see FIG. 1) of the printer engine 150 corresponds to the optical processing mechanism, and includes a Y station 220, an M station 221, a C station 222, a K station 223, an intermediate transfer belt 252, and a secondary transfer outer roller 251. The Y station 220, the M station 221, the C station 222, and the K station 223 have the same configuration, and only differ in colors of images to be formed. The Y station 220 forms a yellow image. The M station 221 forms a magenta image. The C station 222 forms a cyan image. The K station 223 forms a black image. The configuration of the Y station 220 is described here, and description of the configurations of the M station 221, the C station 222, and the K station 223 is omitted.

The Y station 220 includes a photosensitive drum 205, a charging device 211, an exposing device 207, and a developing device 212. The photosensitive drum 205 is a drum-shaped photosensitive member having a photosensitive layer on its surface. The charging device 211 uniformly charges the surface of the photosensitive drum 205 that rotates about a drum shaft. The exposing device 207 scans the charged surface of the photosensitive drum 205 with laser light modulated in accordance with the image data.

The exposing device 207 includes a laser driver, a rotary polygon mirror 208, and a reflecting mirror 209. The laser driver controls light emission of a semiconductor laser (not shown) in accordance with the image data acquired from a controller board 110 (CPU 114). The laser light emitted from the semiconductor laser moves in a main scanning direction in accordance with the rotation of the rotary polygon mirror 208, and is guided by the reflecting mirror 209 to the surface of the photosensitive drum 205. Thus, the laser light scans the surface of the photosensitive drum 205 in a drum axis direction. The surface of the photosensitive drum 205 is exposed with light so that an electrostatic latent image is formed thereon.

The developing device 212 visualizes the electrostatic latent image with toner of a corresponding color to form a toner image on the surface of the photosensitive drum 205. A yellow toner image is formed on the photosensitive drum 205 of the Y station 220. A magenta toner image is formed on the photosensitive drum 205 of the M station 221. A cyan toner image is formed on the photosensitive drum 205 of the C station 222. A black toner image is formed on the photosensitive drum 205 of the K station 223.

The intermediate transfer belt 252 is an endless belt looped around a plurality of rollers such as a secondary transfer inner roller 240, and rotates in the clockwise direction of FIG. 2. The toner images of the respective colors formed on the respective photosensitive drums 205 are transferred in a superimposing manner onto the rotating intermediate transfer belt 252. The toner image is transferred from the photosensitive drum 205 onto the intermediate transfer belt 252 by applying a bias voltage having a polarity reverse to that of the toner image to the intermediate transfer belt 252. In this manner, the intermediate transfer belt 252 bears a full-color toner image. The intermediate transfer belt 252 rotates to convey the toner image carried thereon to a secondary transfer portion formed of the secondary transfer inner roller 240 and the secondary transfer outer roller 251.

The sheet feeding unit 140 corresponds to a feeding mechanism for the sheet S, and includes a storage unit 210, which is a sheet feeding stage for storing the sheet S, conveyance paths, and conveying rollers. The sheet feeding unit 140 conveys the sheet S from the storage unit 210 one by one to the secondary transfer portion. The secondary transfer portion nips and conveys the intermediate transfer belt 252 and the sheet S by the secondary transfer inner roller 240 and the secondary transfer outer roller 251. At this time, a bias voltage having a polarity reverse to that of the toner image is applied to the secondary transfer outer roller 251 so that the toner image is transferred from the intermediate transfer belt 252 onto the sheet S.

The sheet S having the toner image transferred thereon is conveyed to the fixing unit 260 corresponding to the fixing processing mechanism. The fixing unit 260 includes a fixing roller 261, a pressure roller 262, and a circuit board 300. The fixing roller 261 incorporates a heat source. The pressure roller 262 is urged toward the fixing roller 261. The circuit board 300 controls the fixing processing to be performed by the fixing unit 260. The fixing unit 260 nips and conveys the sheet S having the toner image transferred thereon by the fixing roller 261 and the pressure roller 262 so that the toner image is fixed to the sheet S. At this time, the fixing roller 261 heats and melts the toner image, and the sheet S is pressed between the fixing roller 261 and the pressure roller 262.

In the manner described above, the image is printed on the sheet S. In a case of duplex printing, the sheet S having the image printed on its first surface (front surface) is re-conveyed to the secondary transfer portion via a reverse path 270. Through conveyance to the secondary transfer portion via the reverse path 270, an image printing surface of the sheet S is reversed. On the sheet S with image printing surface thereof has been reversed, an image is printed on a second surface (back surface) different from the first surface by the secondary transfer portion and the fixing unit 260.

The sheet S having the image printed thereon passes through the image reading unit 290 provided on the downstream side of the fixing unit 260 in a conveying direction of the sheet so as to be discharged to the outside of the image forming apparatus 100. In a case where the image formed on the sheet S is the image for adjustment for adjusting the image forming condition, the image reading unit 290 is used for reading of this image for adjustment.

### Circuit Board

The image forming apparatus 100 includes various actuators (loads), such as motors and sensors to perform the image forming processing as described above. The actuators are each connected to a circuit board having electronic parts for control mounted thereon. Electronic parts mounted on the circuit board are each connected by a conductive wire. The circuit board according to a first embodiment of the present disclosure is, for example, a printed wiring board using a printed wiring line as the conductive wire.

The electronic parts control the operation of the actuator. A large number of circuit boards are thus provided in the image forming apparatus 100 so as to correspond to the actuators. One or more actuators are controlled by one circuit board. The circuit board is controlled by the CPU 114 of the controller board 110. The controller board 110 on which the CPU 114 is mounted is also an example of the circuit board.

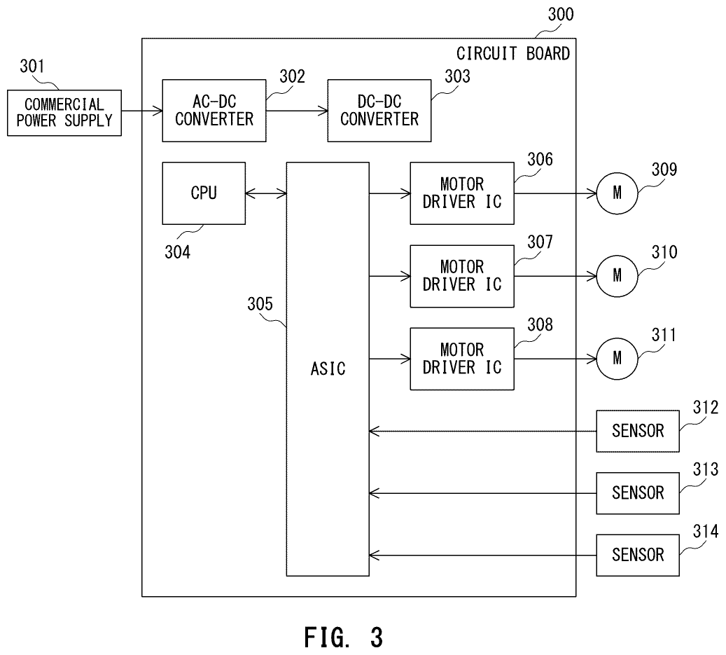

FIG. 3 is a configuration diagram of the circuit board 300 provided in the fixing unit 260. A plurality of motors 309 to 311 in the fixing unit 260 and a plurality of sensors 312 to 314 in the fixing unit 260 are electrically connected to the circuit board 300. Motors 309-311 are actuators (loads) whose operation is controlled by the circuit board 300.

The motor 309 is a drive source for driving the fixing roller 261 being a rotary member. The motor 310 is a drive source for urging the pressure roller 262 toward the fixing roller 261. The motor 311 is a drive source for driving a roller being a rotary member for conveying the sheet S that has been subjected to the fixing processing to the subsequent stage. The sensor 312 is a detector for detecting the sheet S that has been conveyed to the fixing unit 260. The sensor 313 is a temperature detector for detecting the temperature of the fixing roller 261. The sensor 314 is a detector for detecting the sheet S that has been subjected to the fixing processing.

The circuit board 300 implements various functions by a plurality of electronic parts. The example of FIG. 3 includes an AC-DC converter 302 and a DC-DC converter 303. The AC-DC converter 302 is used for generating a predetermined DC voltage from an AC voltage. The DC-DC converter 303 converts a voltage value of the DC voltage. The circuit board 300 further includes a CPU 304, an application specific integrated circuit (ASIC) 305, and motor driver ICs 306 to 308, which are used for control of the actuators. On the circuit board 300, the plurality of semiconductor devices (hereinafter referred to as “ICs”) and surrounding electronic parts corresponding to the ICs as described are mounted as electronic parts.

The AC-DC converter 302 generates, based on AC power supplied from a commercial power supply 301, a power supply voltage which is a DC voltage having a predetermined voltage value. The DC-DC converter 303 generates, based on the power supply voltage supplied from the AC-DC converter 302, a power supply voltage which is a DC voltage having a voltage value different from that of the power supply voltage supplied from the AC-DC converter 302. The supply voltage generated by the DC-DC converter 303 is supplied to the CPU 304 and the ASIC 305. The CPU 304 and the ASIC 305 operate with the power supply voltage supplied from the DC-DC converter 303. The power supply voltage output from the AC-DC converter 302 is supplied to the electronic part and motors 309-311 which operate with a voltage value different from the voltage value for operating the CPU 304 or ASIC 305.

The CPU 304 is connected to each of the motor driver ICs 306 to 308 and each of the sensors 312 to 314 via the ASIC 305. The CPU 304 acquires detection results obtained by each of the sensors 312 to 314 to detect the state of the fixing unit 260 from the detection results. The CPU 304 controls each of the motor driver ICs 306 to 308 via the ASIC 305 in accordance with the detected state of the fixing unit 260, to thereby control the drive of each of the motors 309 to 311. As described above, the CPU 304 and the ASIC 305 control the operation of the fixing unit 260.

The circuit board 300 is provided in the fixing unit 260 and thus controls the operation of the fixing unit 260, and other circuit boards provided in the image forming apparatus 100 similarly control operations of corresponding constituent parts. Each of the circuit boards in the image forming apparatus 100 (including the circuit board 300 and other circuit boards) is connected to the controller board 110 so that communication is allowed therebetween. Communication is allowed between circuit boards via the controller board 110. The circuit boards appropriately control the constituent parts in the image forming apparatus 100 while mutually sharing information on the detection results obtained by the sensors and the control states of the loads.

A large number of electronic parts are mounted on the circuit board. However, for various reasons such as distribution, environment, and accidents, there is a possibility that, for at least a part of electronic parts, a situation in which it becomes difficult to procure occurs. In order to cope with the situation in which there is an electronic part that is difficult to procure (also referred to as “first expected part”), for each of the electronic parts, an electronic part having the same or similar shape and specification may be prepared as a replacement part (also referred to as “second expected part”). In a case where an electronic part (first expected part) cannot be procured, a replacement part (second expected part) of the electronic part is mounted on the circuit board so that the manufacture of the circuit board 300 is continued.

However, in the circuit board 300, for example, a particular IC such as an IC for the DC-DC converter 303 and an IC for the motor driver IC 306 (or 307, 308), at the time of use, inherent surrounding parts may be needed. Further, in some cases, there is no replaceable IC because the number of terminals, arrangement, array, or electrical specification of the IC is different. For these cases, in order to cope with the situation in which the procurement of each electronic part component becomes difficult, a different electronic part component that can achieve the same function as that of an electronic part component including each IC and its surrounding parts is prepared. Those electronic part components are mounted mutually exclusive on the circuit board. With this coping method, a procurable IC is mounted depending on the availability of the mounting part, and hence the manufacture of the circuit board 300 can be continued.

In a case where an electronic part of the first expected part and an electronic part of the second expected part are mounted exclusively on a circuit board, if the circuit board is configured such that the electronic parts of the first and second expected part can be mounted on the same side of the circuit board, the wiring becomes complicated. Further, the area occupied by a wiring pattern becomes large in relation to the circuit board. On the other hand, in a configuration in which the first expected part is mounted on one side of the circuit board and the second expected part is mounted on the other side of the circuit board, by making the wiring patterns as common as possible, the area occupied by the wiring patterns is reduced.

The circuit board has a predetermined arrangement of terminals to be connected to loads such as actuators. For this reason, the electronic parts of the first and second expected parts have the same arrangement of the terminals that supply signals and currents to the load. In a configuration in which the first and second expected parts are mounted exclusively on the same side of the circuit board, there will be no particular problems in the above common arrangement. However, as to the configuration in which the first and second expected parts are mounted on different sides of the circuit board, the arrangement of the terminals that supply signals and currents to the load may be reversed between the first and second expected parts. For example, in a case where the signal sent from the electronic part to the load is a complementary signal, the arrangement of the terminals that output the positive phase signals and negative phase signals will be reversed between the first and second expected parts due to the difference in the surface on which they are mounted. This will prevent the load from operating normally. For example, if the load is a motor, the direction of rotation will be reversed between the first and second expected parts.

The circuit board 300 of the first embodiment has a configuration capable of coping with the situation in which part procurement is difficult, and is further capable of reducing the area required for wiring with properly controlling the electronic part. Now, description is given of a specific circuit configuration and wiring (wiring pattern) of the circuit board 300. In the first embodiment, description is given through use of a configuration of a motor driver IC for controlling a two-phase bipolar-drive stepping motor.

Electronic Part Component

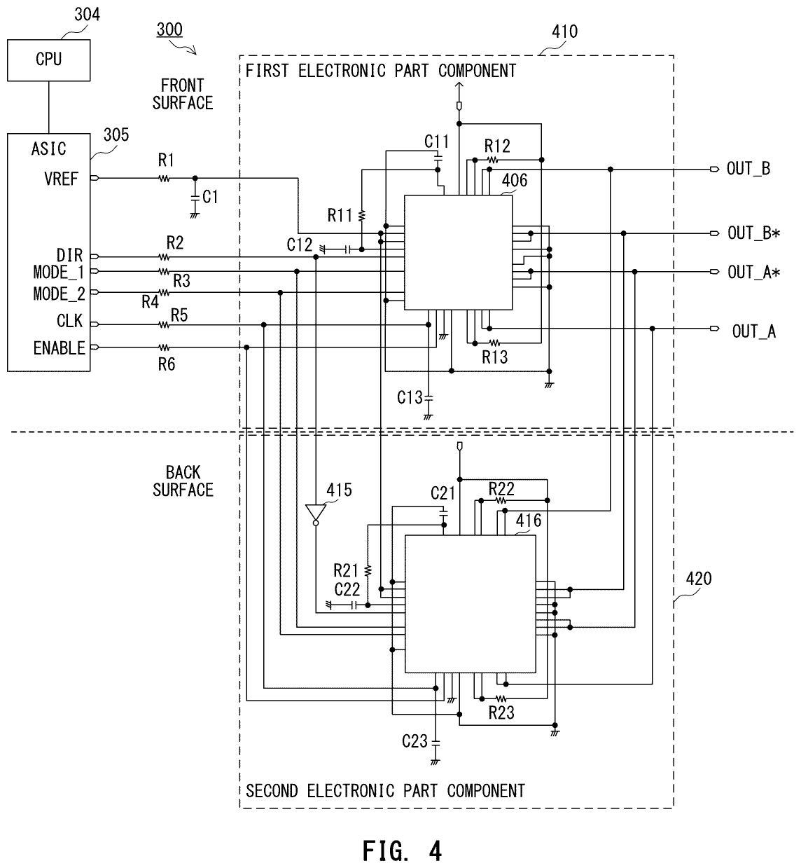

FIG. 4 is an explanatory diagram of electronic part components each including a motor driver IC and its surrounding parts. Those electronic part components are a first electronic part component 410 including a motor driver IC 406, which is a first expected part (genuine product), and a second electronic part component 420 including a motor driver IC 416, which is a second expected part (replacement product) of the motor driver IC 406. The first electronic part component 410 and the second electronic part component 420 have the same functions, and are exclusively mounted on the front surface and the back surface of the circuit board 300, respectively.

The first electronic part component 410 includes resistors R11, R12, and R13 and capacitors C11, C12, and C13 in addition to the motor driver IC 406. The resistors R12 and R13 are detection resistors for detecting currents. The resistor R11 is a resistor for determining a chopping frequency of constant-current pulse width modulation (PWM) control at the time of controlling a motor current. The capacitors C11, C12, and C13 are each provided for noise removal.

Similarly, the second electronic part component 420 includes resistors R21, R22, and R23 and capacitors C21, C22, and C23 in addition to the motor driver IC 416. The resistors R22 and R23 are detection resistors for detecting currents. The resistor R21 is a resistor for determining a chopping frequency of constant-current PWM control at the time of controlling the motor current. The capacitors C21, C22, and C23 are each provided for noise removal.

Control signals branched from the ASIC 305 via damping resistors R1 to R6 are input to the motor driver ICs 406 and 416. The control signals include an ENABLE signal, a CLK signal, a VREF signal, a MODE signal (MODE_1 signal and MODE_2 signal), and a DIR signal. The ENABLE signal is a control signal for enabling the output of the motor driver ICs 406 and 416. The CLK signal is a control signal for controlling a speed of the motor. The VREF signal is a control signal for controlling a value of current flowing through the motor. The MODE signal is a control signal for controlling an excitation pattern of the motor. The DIR signal is a control signal for controlling a rotation direction of the motor. An inverter 415, which is a logic inversion circuit that inverts the logic of the DIR signal, is arranged in the middle of the path for inputting the DIR signal to the motor driver IC 416. As a result, the motor driver IC 406 and the motor driver IC 416 are input with DIR signals with inverted logic.

The motor driver ICs 406 and 416 can drive the motor in accordance with an instruction obtained by those control signals. Phase output signals (OUT_A, OUT_A*, OUT_B, and OUT_B*), which are complementary signals, output from the motor driver ICs 406 and 416 are connected through vias in the shortest distance so as to be input to the motor. The operation of the motor is controlled by those complementary signals input from the motor driver ICs 406 and 416.

The width of the wiring for transmitting the phase output signals OUTA, OUTA*, OUTB, and OUTB* is thicker than the width of the wiring for transmitting control signals since the current for driving the motor flows therethrough. For this reason, the wiring for the phase output signals tends to have less degree of freedom in terms of wiring patterns and to have a larger wiring pattern area. It is necessary to minimize the length of the wiring for the phase output signals to minimize the area of the wiring for the phase output signals.

Further, in the present disclosure, the motor driver IC 406 and the motor driver IC 416 are exclusively mounted on the front surface and the back surface of the circuit board, respectively. At this time, in order to minimize the area of the wiring, it is necessary to connect the wires through which the phase output signals are transmitted in the shortest distance.

The motor driver IC 406 and the motor driver IC 416, which are mounted exclusively, may differ in package size. In the present embodiment, a description is made for a case where the package size of the motor driver IC 416 is larger than the package size of the motor driver IC 406.

The circuit board 300 of the present embodiment has a multilayer structure. Although the circuit board 300 having a four-layer structure will be explained here, any number of layers may be used as long as they are multilayered. The circuit board 300 having the four-layer structure is a double-sided reflow board, and configured such that electronic parts are mountable, with the outermost layers (i.e., one layer (first layer) and the other layer (fourth layer)) being mounting surfaces. The motor driver IC 406 and the motor driver IC 416 are exclusively mounted on a surface of the first layer, which is the first surface (front surface) and a surface of the fourth layer, which is the second surface (back surface), respectively. The second layer 62 is a power supply layer, and includes a load driving power wiring line, which supplies power to the motor driver ICs 406 and 416, and a logic power wiring line, which supplies a low voltage for the CPU 304 and the ASIC 305 etc. The third layer is a ground (GND) layer, and is connected to ground patterns of the first layer and the fourth layer through vias.

### Mounting Region of Circuit Board

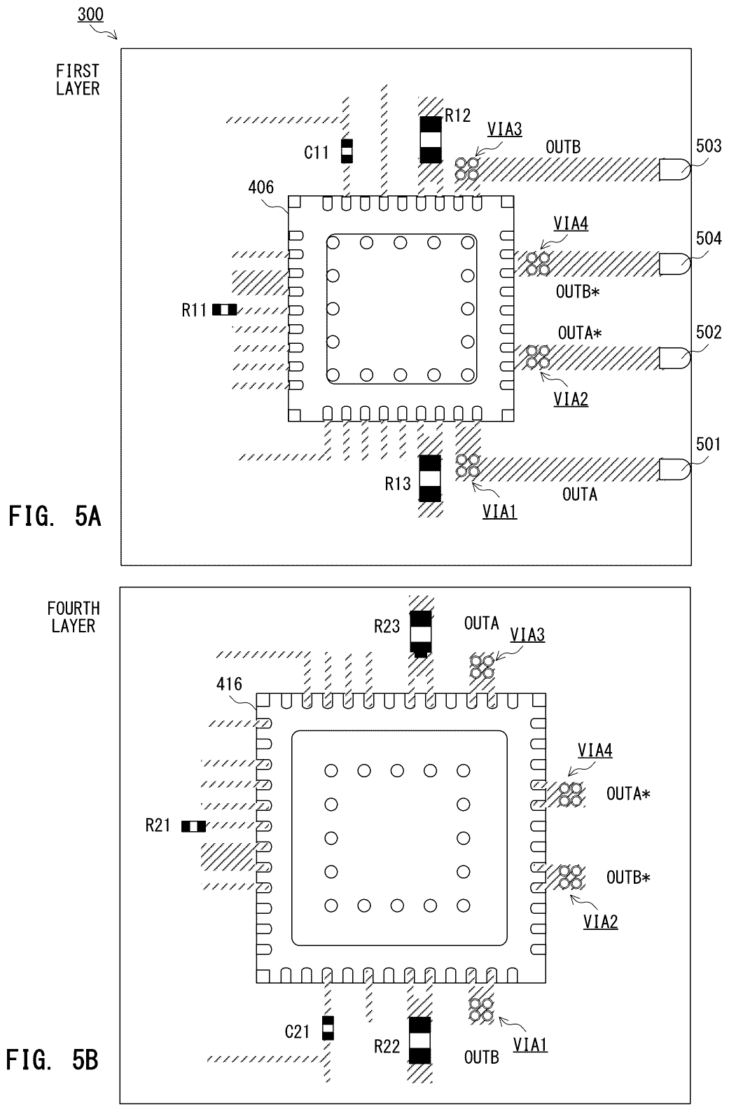

FIGS. 5A and 5B are explanatory views of a mounting surface of a circuit board 300. In the present embodiment, the first electronic part component 410 is mounted on a first surface (front surface) of the first layer, and the second electronic part component 420 is mounted on the second surface (back surface) of the fourth layer. On the mounting surfaces (the first and second surfaces), a wiring pattern is formed using a printing technique, for example, with a conductor such as copper foil. The explanation of the wiring patterns on the second and third layers will be omitted.

In this embodiment, as described with reference to FIG. 4, the first electronic part component 410 and the second electronic part component 420 are exclusively embedded on the front surface and the back surface of the circuit board 300, respectively. The first electronic part component 410 includes the motor driver IC 406, which is a first expected part (genuine product). The second electronic part component 420 includes the motor driver IC 416 which is a second expected part (replacement product) of the motor driver IC 406. A mounting region for the motor driver IC 406 on the front surface and a mounting region for the motor driver IC 416 on the back surface are provided at the same positions (coordinate regions) opposed to each other across the circuit board 300 (second layer and third layer). Thus, the mounting region for the motor driver IC 406 and the mounting region for the motor driver IC 416 are arranged so that they overlap at least partially when viewed from a normal direction of the surface of the circuit board 300. Wiring patterns (shaded area) are formed so that the motor driver ICs 406 and 416 can be mounted in those mounting regions.

The circuit board 300 is equipped with output terminals 501, 502, 503, and 504 for outputting phase output signals OUTA, OUTA*, OUTB, and OUTB* to the motor. In a case where the motor driver IC 406 is mounted, the phase output signal OUTA is output from the output terminal 501, the phase output signal OUTA* is output from the output terminal 502, the phase output signal OUTB is output from the output terminal 503, and the phase output signal OUTB* is output from the output terminal 504.

The motor driver IC 416 has the same arrangement of output terminals that output phase output signals as the motor driver IC 406, so that the same wiring pattern can be used when the motor driver IC 416 is mounted on the surface (first layer) of the circuit board 300 in the same way as the motor driver IC 406 is mounted on the first layer. Therefore, in a case where the motor driver IC 416 is mounted on the back surface (fourth layer) of the circuit board 300, the arrangement of the output terminals that output the phase output signals is reversed to that of the motor driver IC 406.

In other words, the position of the output terminal that outputs the phase output signal OUTA of motor driver IC 416 is opposite to the position of the output terminal that outputs the phase output signal OUTB of the motor driver IC 406, with respect to the circuit board 300. The position of the output terminal that outputs the phase output signal OUTA* of the motor driver IC 416 is opposite to the position of the output terminal that outputs the phase output signal OUTB* of the motor driver IC 406, with respect to the circuit board 300. The position of the output terminal that outputs the phase output signal OUTB* of the motor driver IC 416 is opposite to the position of the output terminal that outputs the phase output signal OUTA* of the motor driver IC 406, with respect to the circuit board 300. The position of the output terminal that outputs the phase output signal OUTB of the motor driver IC 416 is opposite to the position of the output terminal that outputs the phase output signal OUTA of the motor driver IC 406, with respect to the circuit board 300.

A via 3 is provided in a wiring connected to an output terminal that outputs the phase output signal OUTB of the motor driver IC 406. A via 4 is provided in a wiring connected to an output terminal that outputs the phase output signal OUTB* of the motor driver IC 406. A via 2 is provided in a wiring connected to an output terminal that outputs the phase output signal OUTA* of the motor driver IC 406. A via 1 is provided in a wiring connected to an output terminal that outputs the phase output signal OUTA of the motor driver IC 406.

A via 1 is provided in a wiring connected to an output terminal that outputs the phase output signal OUTB of the motor driver IC 416. A via 2 is provided in a wiring connected to an output terminal that outputs the phase output signal OUTB* of the motor driver IC 416. A via 4 is provided in a wiring connected to an output terminal that outputs the phase output signal OUTA* of the motor driver IC 416. A via 3 is provided in a wiring connected to an output terminal that outputs the phase output signal OUTA of the motor driver IC 416.

The vias 1-4 penetrate the circuit board 300 to enable connecting the first layer and the fourth layer of the circuit board 300 electrically. Due to this configuration, the wiring to be connected to the output terminal that outputs the phase output signal OUTA of the motor driver IC 406 and the wiring to be connected to the output terminal that outputs the phase output signal OUTB of the motor driver IC 416 are connected by via 1. The wiring to be connected to the output terminal that outputs the phase output signal OUTA* of the motor driver IC 406 and the wiring to be connected to the output terminal that outputs the phase output signal OUTB* of the motor driver IC 416 are connected by via 2. The wiring to be connected to the output terminal that outputs the phase output signal OUTB of the motor driver IC 406 and the wiring to be connected to the output terminal that outputs the phase output signal OUTA of the motor driver IC 416 are connected by via 3. The wiring to be connected to the output terminal that outputs the phase output signal OUTB* of the motor driver IC 406 and the wiring to be connected to the output terminal that outputs the phase output signal OUTA* of the motor driver IC 416 are connected by via 4.

By using the vias 1-4, the output terminal that outputs the corresponding phase output signal of the motor driver IC 406 and the output terminal that outputs the corresponding phase output signal of the motor driver IC 416 are connected in the shortest distance. Therefore, the area of the circuit pattern of the mounting surface of the first layer and the fourth layer is suppressed. However, as to the wirings of the output terminals that output the same phase output signal, they are not connected to each other. For example, as described above, the wiring connected to the terminal that outputs the phase output signal OUTA of the motor driver IC 406 is connected to the wiring connected to the terminal that outputs the phase output signal OUTB of the motor driver IC 416. Thus, in a case where the motor driver IC 416 is mounted, the phase output signal OUTB is output from the output terminal 501, for example.

Thus, the connection relationship for the phase output signal of the motor driver IC 406 and the motor driver IC 416 is reversed for the motor. This means that the direction of rotation of the motor will be reversed depending on the motor driver IC that is implemented. In this embodiment, an inverter 415 is connected to a terminal to which a DIR signal of the motor driver IC 416 is input, so that the DIR signal controlling the rotation direction of the motor driver IC 416 has an opposite logic to a DIR signal input to the motor driver IC 406.

The inverter 415 reverses the logic of the phase output signals of the motor driver IC 416, thus the logic of the phase output signals of the motor driver IC 416 becomes the same logic as the phase output signals of the motor driver IC 406. This causes the motor to rotate in the appropriate direction. As described above, the DIR signal is a control signal to control the logical values of the phase output signals of the motor driver IC 406 and motor driver IC 416. In addition to the inverter 415, it is also possible to use transistors or FETs (field effect transistors) etc., as the logical inversion circuit.

### Modification example

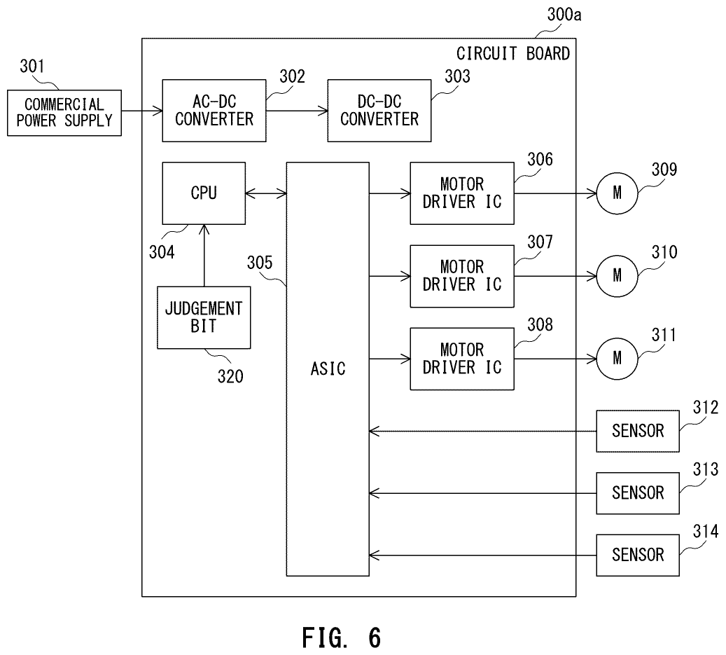

FIG. 6 is a configuration diagram of a modification example of the circuit board 300 provided in the fixing unit 260. The configuration of this circuit board 300a is the same as the configuration shown in FIG. 3, with the addition of a judgment bit unit 320 connected to the CPU 304. The CPU 304 determines a driving control method for each motor 309 to 311 based on the signal output from the judgment bit unit.

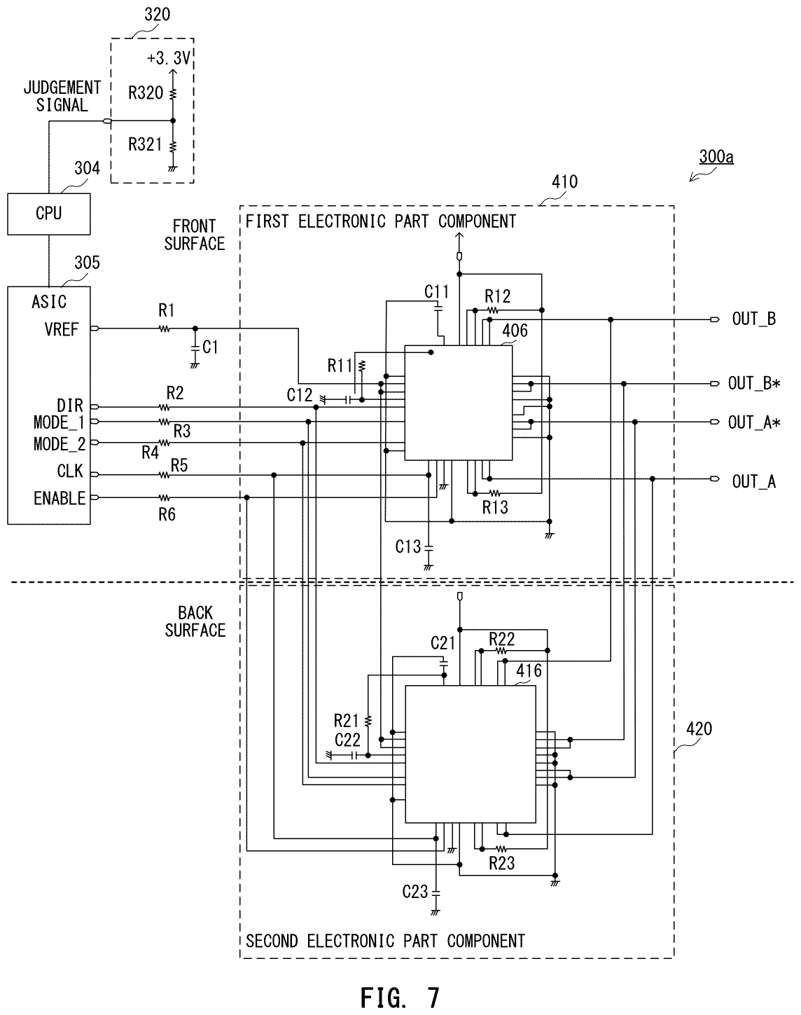

FIG. 7 is an explanatory view of a modification example of the electronic part components each including a motor driver IC and its surrounding parts. Compared to the example of FIG. 4, in the modification example of FIG. 7, the judgment bit unit 320 is added and the inverter 415 is removed. The judgment bit unit 320 includes two resistors R320 and R321 exclusively. In a case where the resistor R320 is provided, the judgment bit unit 320 outputs the power supply voltage (+3.3V) as a judgment signal. In a case where the resistor R321 is provided, the judgment bit unit 320 outputs the ground voltage (0.0V) as the judgment signal. In a case where the first electronic part component 410 is embedded, one of the resistor R320 and the resistor R321 is mounted, and in a case where the second electronic part component 420 is mounted, the other of the resistor R320 and R321 is mounted. Thus, the judgment bit unit 320 outputs, in a case where one of the first electronic part component 410 and the second electronic part component 420 is exclusively mounted, information indicating which of them is implemented.

The CPU 304 acquires the judgment signal from the judgment bit unit 320 to judge which of the motor driver ICs 406 and 416 is mounted. For example, in a case where the judgment signal acquired from the judgment bit unit 320 is a power supply voltage, the CPU 304 judges it to be a logical high and judges that the motor driver IC 406 is mounted. In a case where the judgment signal acquired from the judgment bit unit 320 is a ground voltage, the CPU 304 judges it to be a logical low and determines that the motor driver IC 416 is mounted.

The CPU 304 determines the logic level of the DIR signal that controls the rotation direction of the motor based on the judgment result. For example, in a case where the CPU 304 judges that the motor driver IC 416 is connected, the CPU 304 outputs, as a DIR signal, a control signal that is logically inverted so that the logic of the DIR signal is opposite to that of the motor driver IC 406. As described above, by determining the logic of the DIR signal according to the motor driver IC that is mounted, the phase output signal, which is inverted due to the wiring connection, is further inverted. Thus, the rotation direction of the motor is appropriately controlled.

The signal used to determine, by the CPU 304, which semiconductor device is mounted is not limited to the judgment signal output from the judgment bit unit 320, as long as the signal value changes depending on the mounted semiconductor device. Any signal can be used as such a signal as long as the voltage values when the motor driver IC 406 is mounted and when the motor driver IC 416 is mounted are different from each other.

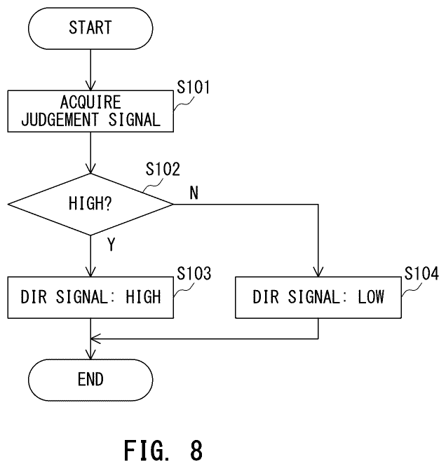

FIG. 8 is a flowchart showing the process of determining the logic of the DIR signal in response to the judgment signal. This process is performed in a case where the motor is driven.

The CPU 304 acquires the judgment signal from the judgment bit unit 320 (step S101). The CPU 304 determines the logic level of the acquired judgment signal (step S102). If the voltage of the judgment signal is the power supply voltage of 3.3V, the CPU 304 judges that the logic level of the judgment signal is high (step S102: Y). In this case, the CPU 304 sets the logic level of the DIR signal to high (step S103). If the voltage of the judgment signal is the ground voltage of 0.0V, the CPU 304 judges that the logic level of the judgment signal is low (step S102: N). In this case, the CPU 304 sets the logic level of the DIR signal to low (step S104). The DIR signal can be generated by the ASIC 305 under the instruction of the CPU 304, and is transmitted from the ASIC 305 to the motor driver ICs which is mounted to the circuit board 300a. Furthermore, the combination of the logic level of the judgment signal and the logic level of the DIR signal is not limited to the above.

With the above-described configuration, as to the circuit board 300 on which two electronic parts or two electronic part components having the same function are mounted exclusively, the space on the mounting surface occupied by the wiring pattern can be suppressed. Specifically, as to two electronic parts or two electronic part components, one can be mounted on the surface of the circuit board 300, and the other can be mounted on the back surface of the circuit board 300, and they are mounted exclusively. The control signals for controlling the load are output from the same terminals of the circuit board 300, therefore, in the two electronic parts, the arrangement of the terminals for outputting the control signals is almost the same. The terminals of the two electronic parts are connected by a through via penetrating the circuit board 300 and connected to the same terminals of the circuit board 300. Due to this configuration, the area of the wiring pattern can be suppressed.

The control signals output from the two electronic parts are complementary signals, for example. In this case, there are two terminals for outputting the control signals, one for the positive phase signal and the other for the negative phase signal. Because the electronic parts are mounted exclusively on the front and back surfaces of the circuit board 300, the arrangement of the terminals for the positive phase signal and the terminals for the negative phase signal is switched depending on the electronic parts mounted. In other words, in a case where the electronic parts are mounted on the same surface, the arrangement of the terminals for the positive phase signal and the terminals for the negative phase signal is the same for the two electronic parts. However, in a case where one of them is mounted on a different surface, the arrangement of the terminals for the positive phase signal and the terminals for the negative phase signal is reversed.

In this case, the terminals for the positive phase signal of the electronic part mounted on the surface of the circuit board 300 and the terminals for the negative phase signal of the electronic part mounted on the back surface are connected by vias. Similarly, the terminals for the negative phase signal of the electronic part mounted on the surface of the circuit board 300 and the terminals for the positive phase signal of the electronic part mounted on the back surface are connected by vias. Therefore, depending on the mounted electronic part, the logic level of the control signal transmitted from the circuit board 300 to the load is reversed. This interferes with the normal operation of the load. If the load is a motor, the motor will rotate in reverse.

In order to prevent this, in this embodiment, the electronic parts are controlled such that the logic level of the positive phase signal and the negative phase signal of the electronic parts to be mounted on the back side is reversed. With such control, the load operates normally. If the load is a motor, the motor will rotate in the correct direction. Therefore, even in a case where the two electronic parts are exclusively mounted on both surfaces of the circuit board 300, the normal operation of the load can be maintained while suppressing the wiring pattern area. As described above, according to this embodiment, the circuit board can be mounted with multiple electronic parts exclusively, and the wiring pattern area can be suppressed while ensuring the normal operation of the load.

In the above embodiment, the first and second expected parts are mounted exclusively on both surfaces of the circuit board. However, the scope of the application of this technology is not limited to the embodiment. For example, in a case where a platform for multiple products with different functions is to be formed, two electronic parts may be exclusively mounted according to the functions required for the product.

Furthermore, this technology may be applied to an embodiment in which both of the two electronic parts are mounted. For example, the two electronic parts may operate exclusively depending on the operating status of the device. This technology is also effective in such cases.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-208451, filed Dec. 11, 2023, which is hereby incorporated by reference herein in its entirety.

What is claimed is:

1. A circuit board comprising:
a first surface configured so that a first electronic part is mountable;
a second surface different from the first surface, the second surface being configured so that a second electronic part is mountable;
a controller configured to generate:
a first control signal to be input to the first electronic part to control a logical value of an output signal output by the first electronic part; and
a second control signal to be input to the second electronic part to control a logical value of an output signal output by the second electronic part; and
a first via configured to connect a wiring to which the output signal from the first electronic part is output and a wiring to which the output signal from the second electronic part is output,
wherein a logical value of the first control signal and a logical value of the second control signal have an inverse relationship with each other.

2. The circuit board according to claim 1,
wherein the first electronic part comprises a first terminal from which a positive phase signal of a first complementary signal is output as the output signal, and
wherein the second electronic part comprises a second terminal from which a positive phase signal of a second complementary signal is output as the output signal.

3. The circuit board according to claim 2, further comprising a second via,
wherein the first electronic part comprises a third terminal from which a negative phase signal of the first complementary signal is output as the output signal,
wherein the second electronic part comprises a fourth terminal from which a negative phase signal of second complementary signal is output as the output signal, and
wherein the second via is connected to the third terminal and the fourth terminal.

4. The circuit board according to claim 3,
wherein an arrangement of the first and third terminals in the first electronic part and an arrangement of the second and fourth terminals in the second electronic part are designed to be reversed by mounting the first and second electronic parts on different surfaces.

5. The circuit board according to claim 1,
wherein the controller has a logical inversion unit, to which a control signal is input, configured to generate the second control signal by inverting the logical value of the first control signal input to the controller.

6. The circuit board according to claim 1,
wherein the output signal output from the first electronic part and the output signal output from the second electronic part are signals that control rotation of a motor.

7. The circuit board according to claim 6, wherein the controller is configured to:
output the first control signal to the first electronic part to control a direction of the rotation of the motor in a first direction in a case where the first electronic part is mounted; and
output the second control signal to the second electronic part to control a direction of the rotation of the motor in a second direction opposite to the first direction in a case where the second electronic part is mounted.

8. The circuit board according to claim 1, further comprising:
a judgment unit configured to output a judgment signal indicating which of the first and second electronic parts is mounted.

9. The circuit board according to claim 8,
wherein the controller is configured to transmit one of the first control signal and the second control signal based on the judgment signal acquired from the judgment unit.

10. The circuit board according to claim 8,
wherein the judgment unit is configured to:
output the judgment signal with a first voltage value in a case where the first electronic part is mounted; and
output the judgment signal with a second voltage value different from the first voltage value in a case where the second electronic part is mounted.

11. The circuit board according to claim 1,
wherein a mounting region of the first electronic part and a mounting region of the second electronic part overlap at least partially when viewed from a normal direction of the first surface.

12. The circuit board according to claim 1,
wherein the first electronic part and the second electronic part are mounted exclusively.

13. An image forming apparatus comprising:
a load configured to perform at least part of image forming; and
a circuit board,
wherein the circuit board includes
a first surface configured so that a first electronic part is mountable,
a second surface different from the first surface, the second surface being configured so that a second electronic part is mountable,
a controller configured to generate a first control signal to be input to the first electronic part to control a logical value of an output signal output by the first electronic part and a second control signal to be input to the second electronic part to control a logical value of an output signal output by the second electronic part, and
a first via configured to connect a wiring to which the output signal from the first electronic part is output and a wiring to which the output signal from the second electronic part is output,
wherein the logical value of the first control signal and the logical value of the second control signal have inverse relationship with each other, and
wherein the first electronic part is mounted on the circuit and the second electronic part is not mounted on the circuit.

14. The image forming apparatus according to claim 13,
wherein the load is a motor, and
wherein the output signal output from the first electronic part and the output signal output from the second electronic part are signals that control rotation of the motor.

15. The image forming apparatus according to claim 14,
wherein the controller is configured to:
output the first control signal to the first electronic part to control a direction of the rotation of the motor in a first direction in a case where the first electronic part is mounted; and
output the second control signal to the second electronic part to control a direction of the rotation of the motor in a second direction opposite to the first direction in a case where the second electronic part is mounted.
